(19) United States
(12) Patent Application Publication
(10) Pub. No.: US 2026/0040776 A1
(43) Pub. Date: Feb. 5, 2026

(54) Display Device

(71) Applicant: LG Display Co., Ltd., Seoul (KR)

(72) Inventors: Bokyoung Lee, Paju-si (KR); Yong-ll Kim, Paju-si (KR); Sunmi Lee, Paju-si (KR)

(21) Appl. No.: 19/252,813

(22) Filed: Jun. 27, 2025

(30) Foreign Application Priority Data
Aug. 1, 2024 (KR) 10-2024-0102289

(51) Int. Cl. H10K 59/124; H10D 86/40; H10D 86/60; H10K 59/121; H10K 59/122; H10K 59/131

(52) U.S. Cl. CPC H10K 59/124; H10D 86/431; H10D 86/60; H10K 59/1213; H10K 59/122; H10K 59/131

(57) ABSTRACT

A display device may comprise a substrate, a first active layer on the substrate and positioned in a first area, a first insulation layer on the first active layer, a second insulation layer on the first insulation layer, a third insulation layer on the second insulation layer, a second active layer on the substrate and positioned in a second area different from the first area, a first gate electrode on the third insulation layer and overlapping at least a portion of the first active layer, a second gate electrode on the third insulation layer and overlapping at least a portion of the second active layer, and a fourth insulation layer on the first gate electrode and the second gate electrode. The second insulation layer may be on the first active layer and under the second active layer, and the second active layer may be buried in the third insulation layer.

### CROSS-REFERENCE TO RELATED APPLICATION

This application claims priority from Republic of Korea Patent Application No. 10-2024-0102289, filed on Aug. 1, 2024, which is hereby incorporated by reference in its entirety.

### FIELD

Embodiments of the disclosure relate to an apparatus and particularly to, for example, without limitation, a display device.

### DESCRIPTION OF RELATED ART

A display panel of a display device may include a display area where an image is displayed and a non-display area where an image is not displayed. A plurality of transistors used to drive the display for displaying images are disposed on the display panel.

To form the plurality of transistors on the display panel, a plurality of metal layers and a plurality of insulation layers may be disposed on the display panel. Thus, the numbers of masks and processes required to manufacture the display panel inevitably increase.

### SUMMARY

Embodiments of the disclosure may provide a display device having a transistor structure having a structure capable of reducing the number of masks and the number of processes.

Embodiments of the disclosure may provide a display device having a different transistor structure for each area.

Embodiments of the disclosure may provide a display device having a transistor structure having a different active layer for each area.

Embodiments of the disclosure may provide a display device having a structure capable of reducing the thickness of a display panel and a structure capable of reducing the numbers of masks and processes, despite having a different transistor structure for each area.

Embodiments of the disclosure may provide a display device having a gate sharing structure while having a different transistor structure for each area.

Embodiments of the disclosure may provide a display device having a gate insulation sharing structure while having a different transistor structure for each area.

A display device according to embodiments of the disclosure may comprise a substrate, a first active layer disposed on the substrate and positioned in a first area, a first insulation layer disposed on the first active layer, a second insulation layer disposed on the first insulation layer, a third insulation layer disposed on the second insulation layer, a second active layer disposed on the substrate and positioned in a second area different from the first area, a first gate electrode disposed on the third insulation layer and overlapping at least a portion of the first active layer, a second gate electrode disposed on the third insulation layer and overlapping at least a portion of the second active layer, and a fourth insulation layer disposed on the first gate electrode and the second gate electrode.

According to the display device according to embodiments of the disclosure, the second insulation layer may be disposed on the first active layer and disposed under the second active layer.

According to the display device according to embodiments of the disclosure, the second active layer may be buried in the third insulation layer. The third insulation layer may be disposed to surround an upper surface, a lower surface, and a side surface of the second active layer. The third insulation layer may be positioned between the second insulation layer and the first gate electrode, between the second insulation layer and the second active layer, and between the second active layer and the second gate electrode. The third insulation layer may be positioned on a side of the second active layer.

A display device according to embodiments of the disclosure may comprise a substrate, a first transistor disposed on the substrate and positioned in a first area, and a second transistor disposed on the substrate and positioned in a second area different from the first area. The first transistor may include a first active layer disposed on the substrate and positioned in the first area, a first gate insulation layer disposed on the first active layer, and a first gate electrode disposed on the first gate insulation layer and overlapping at least a portion of the first active layer. The second transistor may include a second active layer disposed on the substrate and positioned in the second area, a second gate insulation layer disposed on the second active layer, and a second gate electrode disposed on the second gate insulation layer and overlapping at least a portion of the second active layer.

According to the display device according to embodiments of the disclosure, the first gate insulation layer may include an insulating material not included in the second gate insulation layer.

A display device according to embodiments of the disclosure may comprise a substrate, a first transistor disposed on the substrate and positioned in a first area, a second transistor disposed on the substrate and positioned in a second area different from the first area, an insulation layer disposed on the first transistor and the second transistor, and a touch electrode disposed on the insulation layer.

The first transistor may include a first active layer disposed on the substrate and positioned in the first area, a first gate insulation layer disposed on the first active layer, and a first gate electrode disposed on the first gate insulation layer and overlapping at least a portion of the first active layer.

The second transistor may include a second active layer disposed on the substrate and positioned in the second area, a second gate insulation layer disposed on the second active layer, and a second gate electrode disposed on the second gate insulation layer and overlapping at least a portion of the second active layer.

According to the display device according to embodiments of the disclosure, the first gate electrode and the second gate electrode may include the same gate metal. The first active layer may be positioned closer to the substrate than the second active layer.

According to the display device according to embodiments of the disclosure, the touch electrode may be disposed in the second area where the second transistor may be disposed, out of the first area and the second area.

According to embodiments of the disclosure, there may be provided a display device having a transistor structure having a structure capable of reducing the number of masks and the number of processes.

According to embodiments of the disclosure, there may be provided a display device having a different transistor structure for each area.

According to embodiments of the disclosure, there may be provided a display device having a transistor structure having a different active layer for each area.

According to embodiments of the disclosure, there may be provided a display device having a structure capable of reducing the thickness of a display panel and a structure capable of reducing the numbers of masks and processes, despite having a different transistor structure for each area.

According to embodiments of the disclosure, there may be provided a display device having a gate sharing structure while having a different transistor structure for each area.

According to embodiments of the disclosure, there may be provided a display device having a gate insulation sharing structure while having a different transistor structure for each area.

According to embodiments of the disclosure, there may be provided a display device capable of process optimization through a structure capable of reducing the number of masks and the number of processes.

It is to be understood that both the foregoing general description and the following detailed description are exemplary and explanatory and are intended to provide further explanation of the inventive concepts as claimed.

### BRIEF DESCRIPTION OF DRAWINGS

The above and other objects, features, and advantages of the disclosure will be more clearly understood from the following detailed description, taken in conjunction with the accompanying drawings, in which:

FIG. 1 illustrates a display device according to embodiments of the disclosure;

FIG. 2 illustrates a display panel according to an embodiment of the disclosure;

FIG. 3 illustrates a gate-in panel circuit according to embodiments of the disclosure;

FIGS. 4 to 6 are cross-sectional views illustrating a display panel according to embodiments of the disclosure;

FIG. 7 is a cross-sectional view illustrating a display panel according to embodiments of the disclosure; and

FIGS. 8 to 19 illustrate a manufacturing process flow of a display panel according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Any implementation described herein as an “example” is not necessarily to be construed as preferred or advantageous over other implementations.

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure.

Features of various embodiments of the present disclosure may be partially or overall coupled to or combined with each other and may be variously inter-operated with each other and driven technically as those skilled in the art can sufficiently understand. Embodiments of the present disclosure may be carried out independently from each other or may be carried out together in co-dependent relationship.

Hereinafter, various embodiments of the disclosure are described in detail with reference to the accompanying drawings.

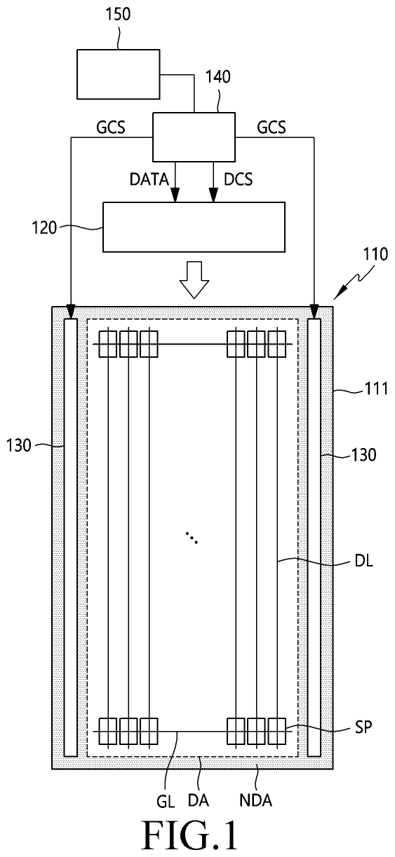

FIG. 1 illustrates a display device 100 according to embodiments of the disclosure.

Referring to FIG. 1, a display device 100 according to embodiments of the disclosure may include a display panel 110 and display driving circuits, as components for displaying images. The display driving circuit may be a circuit for driving the display panel 110. The display driving circuits may include a data driving circuit 120, a gate driving circuit 130, and a controller 140, but embodiments of the disclosure are not limited thereto.

The display panel 110 may include a substrate 111 and a plurality of subpixels SP disposed on the substrate 111.

The substrate 111 may include a display area DA and a non-display area NDA.

The display area DA is an area where images may be displayed and may also be referred to as an active area. A plurality of subpixels SP for image display may be disposed in the display area DA.

The non-display area NDA is an area where no image is displayed and may be an area outside the display area DA. The non-display area NDA may also be referred to as a bezel (or bezel area). The non-display area NDA may include a pad area.

For example, the non-display area NDA may include a first non-display area, a second non-display area, a third non-display area, and a fourth non-display area. The first non-display area may be positioned outside the display area DA in the row direction. The second non-display area may be positioned outside the display area DA in the row direction and may be positioned opposite to the first non-display area. The third non-display area may be positioned outside the display area DA in the column direction. The fourth non-display area may be positioned outside the display area DA in the column direction and may be positioned opposite to the third non-display area.

Among the first to fourth non-display areas, the fourth non-display area may include a pad area where a driving circuit is connected, bonded (or attached), and the first to third non-display areas may have a very small size, but the embodiments of the disclosure are not limited thereto.

As another example, the boundary area between the display area DA and the non-display area NDA may be bent so that the non-display area NDA may be positioned under the display area.

No or little change may be made to the non-display area NDA shown to the user when the user views the display device 100 from the front, but embodiments of the disclosure are not limited thereto.

The display device 100 according to embodiments of the disclosure may be a self-luminous display device in which the display panel 110 emits light by itself, but embodiments of the disclosure are not limited thereto. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal. As another example, the display device 100 according to embodiments of the disclosure may be a micro LED display device or a mini LED display device.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors, but embodiments of the disclosure are not limited thereto.

Various types of signal lines for driving a plurality of subpixels SP may be disposed on the substrate 111 of the display panel 110. For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the column direction. Each of the plurality of gate lines GL may be disposed to extend in the row direction. According to embodiments of the disclosure, the column direction and the row direction may be relative directions. For example, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto. In embodiments of the disclosure, the angle between the row direction and the column direction may be 90 degrees or may an angle different from 90 degrees. Further, in embodiments of the disclosure, the row direction may be referred to as a first direction, and the column direction may be referred to as a second direction.

The data driving circuit 120 may be a circuit for driving the plurality of data lines DL and may out data signals to the plurality of data lines DL.

The data driving circuit 120 may receive digital image data DATA from the controller 140 and may convert the received image data DATA into analog data signals (or also referred to as data voltages) and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The data driving circuit 120 may be connected to one side (e.g., an upper or lower side) of the display panel 110. As another example, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage may be a high level voltage, and the turn-off level voltage may be a low level voltage. As another example, the turn-on level voltage may be a low level voltage, and the turn-off level voltage may be a high level voltage.

In the display device 100 according to embodiments of the disclosure, the gate driving circuit 130 may be embedded, in a gate in panel (GIP) type, in the display panel 110, but embodiments of the disclosure are not limited thereto. When the gate driving circuit 130 is of the gate in panel type, the gate driving circuit 130 may be formed on the substrate 111 of the display panel 110 during the manufacturing process of the display panel 110. When the gate driving circuit 130 is of a gate-in-panel type, the gate driving circuit 130 may be referred to as a gate-in-panel circuit (GIPC).

For example, the gate driving circuit 130 may be disposed in the non-active area NDA of the display panel 110.

As another example, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA). As another example, the gate driving circuit 130 may be disposed over the entire display area DA.

When the gate driving circuit 130 is disposed in the display area DA of the display panel 110, the gate driving circuit 130 may vertically overlap the subpixels SP disposed in the display area DA. For example, the gate driving circuit 130 may vertically overlap the light emitting elements and transistors included in the disposed subpixels SP in the display area DA. The gate driving circuit 130 may vertically overlap a plurality of light emitting elements and a plurality of transistors included in a plurality of subpixels SP disposed in the display area DA. The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be substantially identical. As another example, the first semiconductor material and the second semiconductor material may be different from each other. For example, the first semiconductor material may be a silicon-based semiconductor material (e.g., low temperature poly silicon), and the second semiconductor material may be an oxide semiconductor material. For example, the active layer may be, but is not limited to, a semiconductor layer.

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may receive input image data from the host system 150 and supply image data DATA to the data driving circuit 120 based on the input image data.

The controller 140 may be implemented as a separate component from the data driving circuit 120, or the controller 140 and the data driving circuit 120 may be integrated into an integrated circuit (IC).

The controller 140 may be a timing controller used in display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor, but is not limited thereto.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI), but embodiments of the disclosure are not limited thereto.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is of an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate 111, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit. The power supply circuit may supply various voltages and power voltages related to display driving to the display driving circuit or display panel 110.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays, but embodiments of the disclosure are not limited thereto.

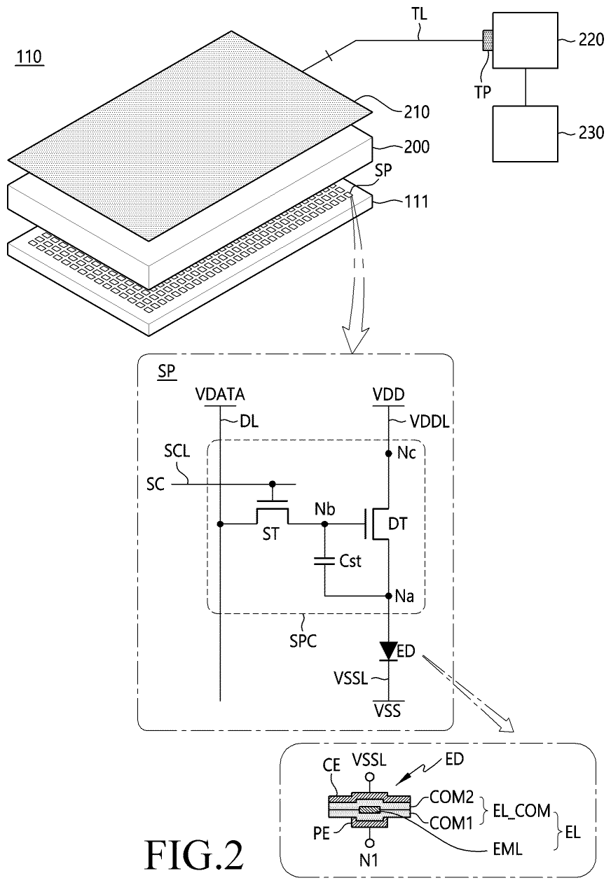

FIG. 2 illustrates a display panel 110 according to an embodiment of the disclosure.

Referring to FIG. 2, the display panel 110 may include a substrate 111, a plurality of subpixels SP on the substrate, and an encapsulation layer 200 on the substrate 111. The encapsulation layer 200 may also be referred to as an encapsulation substrate or an encapsulation unit.

Referring to FIG. 2, when the display device 100 according to embodiments of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but embodiments of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC which is a kind of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP or may be disposed commonly over a plurality of subpixels SP. The common intermediate layer EL_COM may be commonly disposed across the plurality of subpixels SP, but embodiments of the disclosure are not limited thereto.

The light emitting layer EML may be disposed for each emission area. The common intermediate layer EL_COM may be commonly disposed across a plurality of emission areas and non-emission areas, but embodiments of the disclosure are not limited thereto.

For example, the first common intermediate layer COM1 may include a hole injection layer HIL, an electron blocking layer EBL, and a hole transport layer HTL, but embodiments of the disclosure are not limited thereto. The second common intermediate layer COM2 may include an electron transport layer ETL, a hole blocking layer HBL, and an electron injection layer EIL, but embodiments of the disclosure are not limited thereto.

The hole injection layer HIL may inject holes from the pixel electrode PE to the hole transport layer HTL, and the hole transport layer HTL may transport holes to the light emitting layer EML. The electron injection layer EIL may inject electrons from the common electrode CE to the electron transport layer ETL, and the electron transport layer ETL may transport electrons to the light emitting layer EML.

For example, the common electrode CE may be electrically connected to the base voltage line VSSL. A base voltage VSS, which is a type of common driving signal, may be applied to the common electrode CE through the base voltage line VSSL. The pixel electrode PE may be electrically connected directly or indirectly (through another transistor) to the first node Na of the driving transistor DT of each subpixel SP. In the disclosure, “base voltage VSS” may also be referred to as a “low-potential power voltage” or a “low-potential voltage,” and “base voltage line VSSL” may also be referred to as a “low-potential power voltage line” or a “low-potential voltage line.”

Each light emitting element ED may include portions where the pixel electrode PE, the light emitting layer EML in the intermediate layer LE, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), a quantum dot light emitting element, a micro LED, or a mini LED, but embodiments of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node Na, a second node Nb, and a third node Nc. The first node Na may be electrically connected to the light emitting element ED, the second node Nb may receive a data signal VDATA, and the third node Nc may receive a driving voltage VDD from the driving voltage line VDDL. The driving transistor DT may be connected on the first node Na and the third node Nc.

In the driving transistor DT, the second node Nb may be a gate node, the first node Na may be a source node or a drain node, and the third node Nc may be a drain node or a source node. Hereinafter, for convenience of description, an example is described in which in the driving transistor DT, the second node Nb may be a gate node, the first node Na may be a source node, and the third node Nc may be a drain node, but embodiments of the disclosure are not limited thereto.

The scan transistor ST included in the subpixel circuit SPC illustrated in FIG. 2 may be a switching transistor for transferring the data signal VDATA, which is an image signal, to the second node Nb, which is the gate node of the driving transistor DT.

The scan transistor ST may be controlled to be turned on and off by the scan signal SC, which is a kind of gate signal applied through the scan line SCL, which is a type of the gate line GL, to control electrical connection between the second node Nb of the driving transistor DT and the data line DL. The drain electrode or the source electrode of the scan transistor ST may be electrically connected to the data line DL, the source electrode or the drain electrode of the scan transistor ST may be electrically connected to the second node Nb of the driving transistor DT, and the gate electrode of the scan transistor ST may be electrically connected to the scan line SCL.

The storage capacitor Cst may be electrically connected between the first node Na and second node Nb of the driving transistor DT. The storage capacitor Cst may include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

The capacitor Cst may be an external capacitor intentionally designed to be outside the driving transistor DT, but not a parasite capacitor (e.g., Cgs or Cgd) which is an internal capacitor that may be present between the first node Na and the second node Nb of the driving transistor DT, but embodiments of the disclosure are not limited thereto.

Each of the driving transistor DT and the scan transistor ST may be an n-type transistor or a p-type transistor, but embodiments of the disclosure are not limited thereto. For example, one of the driving transistor DT and the scan transistor ST may be either an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. Accordingly, the area of the emission area may increase and the aperture ratio may increase.

When the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and the number of common driving signals supplied to the subpixel SP may vary depending on the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 may be disposed on the display panel 110. The encapsulation layer 200 may prevent or reduce external moisture or oxygen from penetrating into circuit elements (e.g., the light emitting element ED). The encapsulation layer 200 may be configured in various forms so that the light emitting elements ED do not contact moisture or oxygen. For example, the encapsulation layer 200 may be constituted of two or more layers in which organic films and inorganic films are alternately stacked, but embodiments of the disclosure are not limited thereto.

Referring to FIG. 2, a display device 100 according to embodiments of the disclosure may include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 may be embedded in the display panel 110. For example, the touch sensor layer 210 may be disposed on the encapsulation layer 200 in the display panel 110. The touch sensor layer 210 may be a touch unit.

The display panel 110 may further include a plurality of touch pads TP electrically connected to the touch driving circuit 220 and a plurality of touch routing lines for electrically connecting the plurality of sensor electrodes included in the touch sensor layer 210 to the plurality of touch pads TP connected to the touch driving circuit 220.

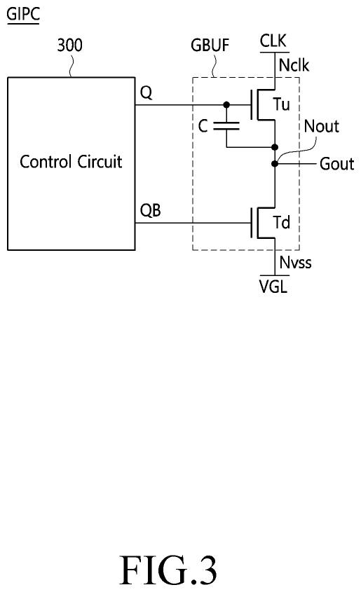

FIG. 3 illustrates a gate-in panel circuit GIPC according to embodiments of the disclosure.

Referring to FIG. 3, the gate driving circuit 130 according to embodiments of the disclosure may be a gate-in-panel circuit (GIPC) formed on the display panel 110.

The gate-in-panel circuit GIPC may include a plurality of gate output circuits G-BUF for outputting a plurality of gate signals Gout and a control circuit 300 for controlling the plurality of gate output circuits G-BUF. Here, the plurality of gate signals Gout may include a scan signal SC.

Each of the plurality of gate output circuits G-BUF may receive a clock signal CLK and a low level voltage VGL and output a gate signal Gout to a gate output node Nout. The gate output node Nout may be connected to the gate line GL.

The gate output circuit G-BUF may include a pull-up transistor Tu to which the clock signal CLK is input and a pull-down transistor Td to which the low level voltage VGL is input.

The gate output circuit G-BUF may output the gate signal Gout to the gate output node Nout to which the pull-up transistor Tu and the pull-down transistor Td are connected.

The pull-up transistor Tu may be connected between the clock signal input node Nclk and the gate output node Nout, and may switch the connection between the clock signal input node Nclk and the gate output node Nout.

The pull-down transistor Td may be connected between the low level voltage node Nvss and the gate output node Nout, and may switch the connection between the low level voltage node Nvss and the gate output node Nout.

In the pull-up transistor Tu, a capacitor C may be electrically connected between the first control node Q, which is a gate node, and the gate output node Nout. The capacitor C may serve to boost the voltage of the first control node Q according to a voltage change of the gate output node Nout.

The control circuit 300 may control the voltage of the first control node Q electrically connected to the gate node of the pull-up transistor Tu, and control the voltage of the second control node QB electrically connected to the gate node of the pull-down transistor Td. Here, the second control node QB may receive a DC voltage or an AC signal through a transistor.

The control circuit 300 may include a plurality of transistors to control the voltage of each of the first control node Q and the second control node QB. For example, the control circuit 300 may include one or more transistors for charging the first control node Q, one or more transistors for discharging the first control node Q, one or more transistors for charging the second control node QB, and one or more transistors for discharging the second control node QB.

In order to control the voltage of each of the first control node Q and the second control node QB, the control circuit 300 may receive a start signal, a reset signal, or the like, and may further receive a carry signal according to a gate driving method.

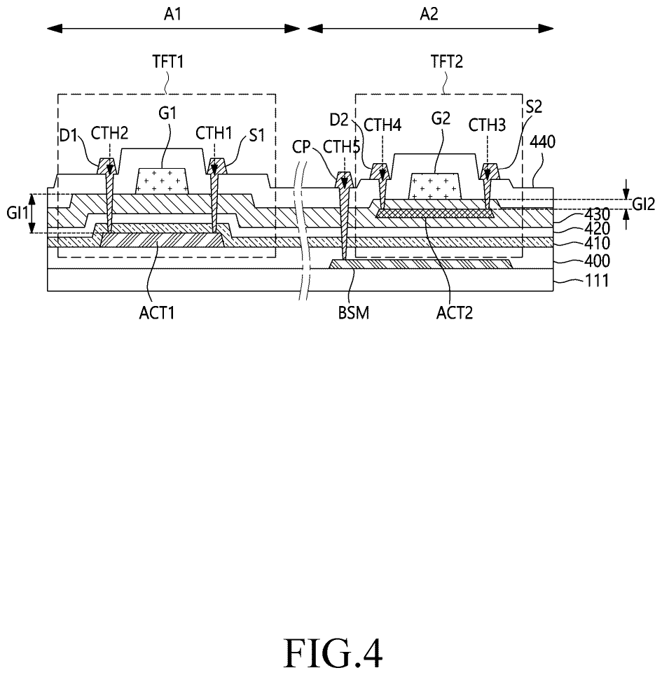

FIGS. 4 to 6 are cross-sectional views illustrating a display panel 110 according to embodiments of the disclosure.

Referring to FIGS. 4 to 6, the display device 100 according to embodiments of the disclosure may include a substrate 111, a first transistor TFT1 disposed on the substrate 111 and positioned in the first area A1, and the second transistor TFT2 disposed on the substrate 111 and positioned in a second area A2 different from the first area A1.

Referring to FIGS. 4 to 6, the first transistor TFT1 may include a first active layer ACT1 disposed on the substrate 111 and positioned in the first area A1, a first gate insulation layer GI1 disposed on the first active layer ACT1, and a first gate electrode G1 disposed on the first gate insulation layer GI1 and overlapping at least a portion of the first active layer ACT1.

Referring to FIGS. 4 to 6, the second transistor TFT2 may include a second active layer ACT2 disposed on the substrate 111 and positioned in the second area A2, a second gate insulation layer GI2 disposed on the second active layer ACT2, and a second gate electrode G2 disposed on the second gate insulation layer GI2 and overlapping at least a portion of the second active layer ACT2.

According to the display device 100 according to embodiments of the disclosure, the first active layer ACT1 may be positioned closer to the substrate 111 than the second active layer ACT2.

According to the display device 100 according to embodiments of the disclosure, the first active layer ACT1 and the second active layer ACT2 may include different semiconductor materials. For example, the first active layer ACT1 may include low temperature polysilicon (LTPS), and the second active layer ACT2 may include an oxide semiconductor material.

According to the display device 100 according to embodiments of the disclosure, the first gate insulation layer GI1 may include an insulating material that is not included in the second gate insulation layer GI2.

According to the display device 100 according to embodiments of the disclosure, the first gate insulation layer GI1 may include a first insulation layer 410 including a first insulating material, a second insulation layer 420 including a second insulating material, and a third insulation layer 430 including a third insulating material.

According to the display device 100 according to embodiments of the disclosure, the second gate insulation layer GI2 may include the first insulating material and may not include the second insulating material.

According to the display device 100 according to embodiments of the disclosure, the second gate insulation layer GI2 may include a portion of the third insulation layer 430.

According to the display device 100 according to embodiments of the disclosure, the second insulation layer 420 included in the first gate insulation layer GI1 may be disposed under the second active layer ACT2.

Referring to FIGS. 4 to 6, according to the display device 100 according to embodiments of the disclosure, the first gate insulation layer GI1 may include a second gate insulation layer GI2. Accordingly, when the first gate insulation layer GI1 is formed, the second gate insulation layer GI2 may also be formed, thereby reducing the number of processes.

Referring to FIGS. 4 to 6, the first gate electrode G1 and the second gate electrode G2 may be disposed together on the third insulation layer 430.

According to the display device 100 according to embodiments of the disclosure, it may have a gate sharing structure. According to the gate sharing structure, the first gate electrode G1 and the second gate electrode G2 may be disposed in the same gate metal layer. Accordingly, the first gate electrode G1 and the second gate electrode G2 may be formed together, so that the number of masks and the number of processes may be decreased.

For example, the first gate insulation layer GI1 may include nitrogen (N), and the second gate insulation layer GI2 may not include nitrogen (N).

For example, among the first insulation layer 410, the second insulation layer 420, and the third insulation layer 430 included in the first gate insulation layer GI1, the second insulating material included in the second insulation layer 420 positioned at the center may include nitrogen (N).

Among the first to third insulation layers 410, 420, and 430 included in the first gate insulation layer GI1, the first and third insulation layers 410 and 430 positioned over and under the second insulation layer 420 positioned at the center may include first and third insulating materials different from the second insulating material included in the second insulation layer 420.

For example, the second insulating material may include nitrogen (N). The first insulating material and the third insulating material may not include nitrogen (N), but may include oxygen (O). For example, the third insulating material may be the same as the first insulating material.

Referring to FIGS. 4 to 6, the first area A1 may be included in the non-display area NDA where an image is not displayed, and the second area A2 may be included in the display area DA where an image is displayed, for example.

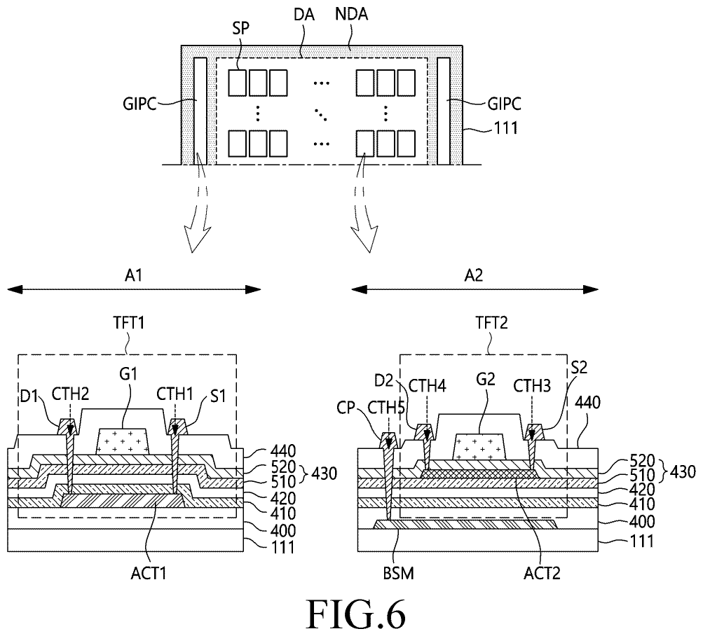

Referring to FIG. 6, the first area A1 may be included in an area where the gate-in-panel circuit GIPC is disposed, and the second area A2 may be included in an area where the subpixel SP is disposed, for example. The gate-in-panel circuit GIPC may be disposed in the non-display area NDA or the display area DA.

Hereinafter, the display device 100 according to embodiments of the disclosure described above is described in more detail.

Referring to FIGS. 4 to 6, a display device 100 according to embodiments of the disclosure may include a substrate 111, a first active layer ACT1 disposed on the substrate 111 and positioned in a first area A1, a first insulation layer 410 disposed on the first active layer ACT1, a second insulation layer 420 disposed on the first insulation layer 410, a third insulation layer 430 disposed on the second insulation layer 420, a second active layer ACT2 disposed on the substrate 111 and positioned in a second area A2 different from the first area A1, a first gate electrode G1 disposed on the third insulation layer 430 and overlapping at least a portion of the first active layer ACT1, a second gate electrode G2 disposed on the third insulation layer 430 and overlapping at least a portion of the second active layer ACT2, and a fourth insulation layer 440 disposed on the first gate electrode G1 and the second gate electrode G2.

Referring to FIGS. 4 to 6, the display device 100 according to embodiments of the disclosure has a transistor structure and an insulation layer structure capable of reducing the number of masks and the number of processes.

According to the display device 100 according to embodiments of the disclosure, the first insulation layer 410 may be positioned on the first active layer ACT1 and under the second active layer ACT2.

According to the display device 100 according to embodiments of the disclosure, the second insulation layer 420 may be positioned on the first active layer ACT1 and under the second active layer ACT2.

Referring to FIGS. 4 to 6, according to the display device 100 according to embodiments of the disclosure, the second active layer ACT2 may be buried in the third insulation layer 430. Accordingly, the third insulation layer 430 may be disposed to surround all of the surfaces of the second active layer ACT2. In other words, the third insulation layer 430 may be disposed to surround the upper surface, the rear surface, and the side surface of the second active layer ACT2.

According to the display device 100 according to embodiments of the disclosure, the third insulation layer 430 may be positioned between the second insulation layer 420 and the first gate electrode G1, between the second insulation layer 420 and the second active layer ACT2, and between the second active layer ACT2 and the second gate electrode G2.

According to the display device 100 according to embodiments of the disclosure, the third insulation layer 430 may be positioned on the side of the second active layer ACT2.

Referring to FIGS. 4 to 6, according to the display device 100 according to embodiments of the disclosure, the first gate electrode G1 and the second gate electrode G2 may include the same gate metal. The first gate electrode G1 and the second gate electrode G2 may be disposed in the same gate metal layer.

Referring to FIGS. 4 to 6, the display device 100 according to embodiments of the disclosure may further include a buffer layer 400 disposed between the substrate 111 and the first insulation layer 410, and a lower pattern BSM disposed between the buffer layer 400 and the first insulation layer 410.

The lower pattern BSM may overlap at least a portion of one of the first active layer ACT1 and the second active layer ACT2. For example, as illustrated in FIGS. 4 to 6, the lower pattern BSM may overlap at least a portion of the second active layer ACT2. The display device 100 according to embodiments of the disclosure may further include a lower pattern overlapping at least a portion of the first active layer ACT1.

The lower pattern BSM may be positioned in the second area A2.

Referring to FIGS. 4 to 6, the display device 100 according to embodiments of the disclosure may further include a connection pattern CP disposed on the fourth insulation layer 440.

The connection pattern CP may be electrically connected to the lower pattern BSM through a fifth contact hole CTH5 penetrating the first to fourth insulation layers 410, 420, 430, and 440 and the buffer layer 400.

The connection pattern CP may be positioned in the second area A2.

Referring to FIGS. 4 to 6, the first active layer ACT1 may include a polysilicon semiconductor material, and the second active layer ACT2 may include an oxide semiconductor material, for example. For example, the first active layer ACT1 may include low temperature polysilicon (LTPS), and the second active layer ACT2 may include an oxide semiconductor material.

According to the display device 100 according to embodiments of the disclosure, the first insulation layer 410 may include a first insulating material, the second insulation layer 420 may include a second insulating material, and the third insulation layer 430 may include a third insulating material.

For example, the second insulating material may be an insulating material different from the first insulating material and the third insulating material.

For example, the first insulating material and the third insulating material may be different insulating materials, the same insulating material, or insulating materials composed of the same elements.

For example, the second insulating material may include nitrogen (N), and the first insulating material and the third insulating material may not include nitrogen (N), but may include oxygen (O). The first insulating material, the second insulating material, and the third insulating material may include silicon (Si) in common. For example, the first insulating material and the third insulating material may be silicon oxide (SiOx), and the second insulating material may be silicon nitride (SiNx).

According to the display device 100 according to embodiments of the disclosure, the fourth insulation layer 440 may include a fourth insulating material different from the second insulating material.

For example, the fourth insulating material may be an insulating material different from the second insulating material.

For example, the fourth insulating material may be an insulating material different from the first insulating material and/or the third insulating material, the same insulating material as the first insulating material and/or the third insulating material, or an insulating material composed of the same elements as the first insulating material and/or the third insulating material.

For example, the fourth insulating material may not include nitrogen (N), but may include oxygen (O). For example, the fourth insulating material may be silicon oxide (SiOx).

The fourth insulation layer 440 is disposed between the gate metal and the first source-drain metal and may also be referred to as a first interlayer insulation layer.

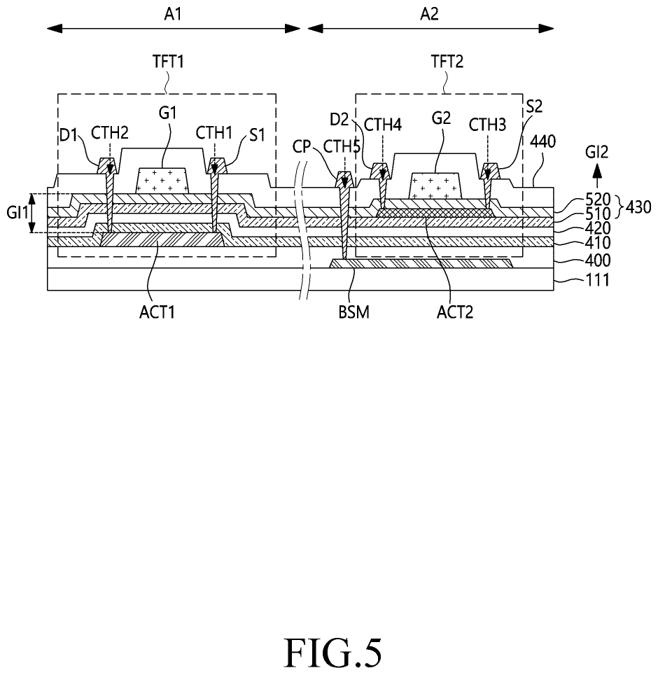

Referring to FIG. 5, according to the display device 100 according to embodiments of the disclosure, the third insulation layer 430 may include a first sub insulation layer 510 and a second sub insulation layer 520.

Referring to FIG. 5, the first sub insulation layer 510 may be disposed between the second insulation layer 420 and the second active layer ACT2. The second sub insulation layer 520 may be disposed between the second active layer ACT2 and the second gate electrode G2.

Referring to FIG. 5, the first sub insulation layer 510 and the second sub insulation layer 520 may include the same insulating material. For example, the first sub insulation layer 510 and the second sub insulation layer 520 may include silicon oxide (SiOx).

Referring to FIG. 5, out of the first sub insulation layer 510 and the second sub insulation layer 520, the second sub insulation layer 520 may be disposed between the second active layer ACT2 and the second gate electrode G2, and the first sub insulation layer 510 may be disposed under the second active layer ACT2 without being disposed between the second active layer ACT2 and the second gate electrode G2.

Referring to FIG. 5, the first sub insulation layer 510 and the second sub insulation layer 520 may be disposed between the first active layer ACT1 and the first gate electrode G1.

Referring to FIG. 5, the display device 100 according to embodiments of the disclosure may further include the first source electrode S1 and the first drain electrode D1 of the first transistor TFT1. The first source electrode S1 may be disposed on the fourth insulation layer 440 and may be electrically connected to a first source contact portion that is a partial area of the first active layer ACT1 through a first contact hole CTH1. The first drain electrode D1 may be disposed on the fourth insulation layer 440 and may be electrically connected to a first drain contact portion that is another partial area of the first active layer ACT1 through a second contact hole CTH2.

Referring to FIG. 5, the display device 100 according to embodiments of the disclosure may further include the second source electrode S2 and the second drain electrode D2 of the second transistor TFT2. The second source electrode S2 may be disposed on the fourth insulation layer 440 and may be electrically connected to the second source contact portion of the second active layer ACT2 through a third contact hole CTH3. The second drain electrode D2 may be disposed on the fourth insulation layer 440 and may be electrically connected to the second drain contact portion of the second active layer ACT2 through a fourth contact hole CTH4.

Referring to FIG. 5, each of the first contact hole CTH1 and the second contact hole CTH2 may penetrate the first to fourth insulation layers 410, 420, 430, and 440. Each of the third contact hole CTH3 and the fourth contact hole CTH4 may penetrate the second sub insulation layer 520 and the fourth insulation layer 440.

The insulating material included in the first sub insulation layer 510 and the insulating material included in the second sub insulation layer 520 may be the same. The insulating material included in the first sub insulation layer 510 and the insulating material included in the second sub insulation layer 520 may be different from the insulating material included in the second insulation layer 420.

For example, the insulating material included in the first sub insulation layer 510 and the insulating material included in the second sub insulation layer 520 may be silicon oxide (SiOx), and the insulating material included in the second insulation layer 420 may be silicon nitride (SiNx).

Referring to FIG. 5, according to the display device 100 according to embodiments of the disclosure, the first insulation layer 410, the second insulation layer 420, and the third insulation layer 430 may constitute the first gate insulation layer GI1 between the first active layer ACT1 and the first gate electrode G1. The third insulation layer 430 may include a first sub insulation layer 510 and a second sub insulation layer 520. The second sub insulation layer 520 may constitute a second gate insulation layer GI2 between the second active layer ACT2 and the second gate electrode G2.

Referring to FIG. 5, the display device 100 according to embodiments of the disclosure may have a gate insulation sharing structure. According to the gate insulation sharing structure, the first gate insulation layer GI1 and the second gate insulation layer GI2 may include a second sub insulation layer 520 in common.

Referring to FIG. 6, according to the display device 100 according to embodiments of the disclosure, the first area A1 may be included in the non-display area NDA different from the display area DA, and the second area A2 may be included in the display area DA where an image is displayed.

Accordingly, the first transistor TFT1 may be disposed in the non-display area NDA, and the second transistor TFT2 may be disposed in the display area DA.

Referring to FIG. 6, according to the display device 100 according to embodiments of the disclosure, the first area A1 may be included in an area where the gate-in-panel circuit GIPC is formed, and the second area A2 may be included in an area where the subpixel SP is formed.

Accordingly, the first transistor TFT1 may be one of the transistors included in the gate-in-panel circuit GIPC, and the second transistor TFT2 may be one of the transistors included in the subpixel SP.

For example, when the first transistor TFT1 is a pull-up transistor Tu or a pull-down transistor Td included in the gate-in panel circuit GIPC, the first transistor TFT1 may output a gate signal to the gate line GL.

When the second transistor TFT2 is a transistor included in the subpixel SP, the second transistor TFT2 may be electrically connected to the light emitting element ED.

For example, the first transistor TFT1 may be disposed in the non-display area NDA or included in the gate-in-panel circuit GIPC and may be a low-temperature polysilicon transistor (LTPS transistor). The second transistor TFT2 may be disposed in the display area DA or included in the subpixel SP and may be an oxide transistor.

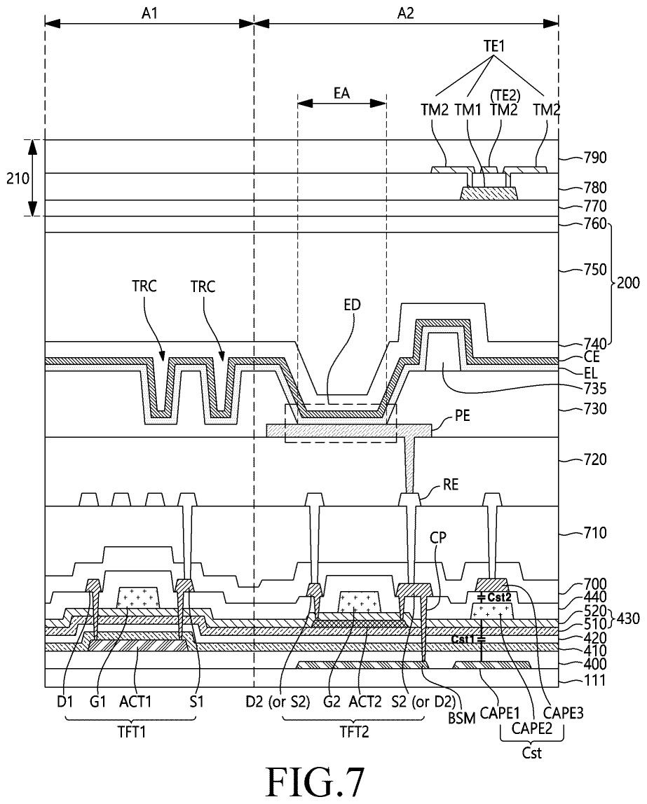

FIG. 7 is a cross-sectional view of a display panel 110 according to embodiments of the disclosure.

Referring to FIG. 7, the display panel 110 may include a first area A1 and a second area A2. A first transistor TFT1 may be disposed in the first area A1, and a second transistor TFT1 may be disposed in the second area A2.

The first transistor TFT1 may include a first active layer ACT1, a first source electrode S1, a first drain electrode D1, and a first gate electrode G1, and the second transistor TFT2 may include a second active layer ACT2, a second source electrode S2, a second drain electrode D2, and a second gate electrode G2.

Referring to FIG. 7, a storage capacitor Cst may be further disposed in the second area A2. The storage capacitor Cst may include a first capacitor electrode CAPE1, a second capacitor electrode CAPE2, and a third capacitor electrode CAPE3.

Hereinafter, a vertical structure of the display panel 110 is described in more detail with reference to FIG. 5.

A lower pattern BSM may be disposed on the substrate 111. The first capacitor electrode CAPE may be disposed on the substrate 111, similarly to the lower pattern BSM. The lower pattern BSM and the first capacitor electrode CAPE1 may be formed of the same metal material. The lower pattern BSM and the first capacitor electrode CAPE1 may be positioned in the second area A2.

The buffer layer 400 may be disposed on the lower pattern BSM and the first capacitor electrode CAPE1.

The first active layer ACT1 may be disposed on the buffer layer 400. The first active layer ACT1 may be positioned in the first area A1.

A first insulation layer 410 may be disposed on the buffer layer 400 and the first active layer ACT1. The first insulation layer 410 may be formed of a first insulating material. For example, the first insulating material may include silicon oxide (SiOx).

The second insulation layer 420 may be disposed on the first insulation layer 410. The second insulation layer 420 may be formed of a second insulating material. For example, the second insulating material may include silicon nitride (SiNx).

The first sub insulation layer 510 may be disposed on the second insulation layer 420.

The second active layer ACT2 may be disposed on the first sub insulation layer 510. The second active layer ACT2 may be positioned in the second area A2. The second active layer ACT2 may be positioned farther from the substrate 111 than the first active layer ACT1. In other words, the first active layer ACT1 may be positioned closer to the substrate 111 than the second active layer ACT2.

The second gate electrode G2 may be disposed on the second active layer ACT2. The second gate electrode G2 may overlap the second active layer ACT2.

The second sub insulation layer 520 may be disposed on the first sub insulation layer 510 and the second active layer ACT2. The second active layer ACT2 may be disposed between the first sub insulation layer 510 and the second sub insulation layer 520.

The first sub insulation layer 510 and the second sub insulation layer 520 may constitute a third insulation layer 430. The first sub insulation layer 510 and the second sub insulation layer 520 may be formed of the same third insulating material. For example, the third insulating material may include silicon oxide (SiOx).

The first gate electrode G1 and the second gate electrode G2 may be disposed on the second sub insulation layer 520. The first gate electrode G1 may be positioned in the first area A1, and the second gate electrode G2 may be positioned in the second area A2.

The first gate electrode G1 and the second gate electrode G2 may include the same gate metal.

The second capacitor electrode CAPE2 may be disposed on the second sub insulation layer 520. The second capacitor electrode CAPE2 may be formed of the same gate metal as the first gate electrode G1 and the second gate electrode G2. The second capacitor electrode CAPE2 may be positioned in the second area A2.

Among the first to third insulation layers 410, 420, and 430, the second insulation layer 420 positioned between the first insulation layer 410 and the third insulation layer 430 may include an insulating material different from that of the first insulation layer 410 and the third insulation layer 430.

The fourth insulation layer 440 may be disposed on the first gate electrode G1, the second gate electrode G2, and the second capacitor electrode CAPE2.

The first source electrode S1, the first drain electrode D1, the second source electrode S2, and the second drain electrode D2 may be disposed on the fourth insulation layer 440. The first source electrode S1, the first drain electrode D1, the second source electrode S2, and the second drain electrode D2 may be formed of the same first source-drain metal.

The first source electrode S1 and the first drain electrode D1 may be positioned in the first area A1, and the second source electrode S2 and the second drain electrode D2 may be positioned in the second area A2.

The first source electrode S1 may be connected to a portion of the first active layer ACT1 through a contact hole of the first to fourth insulation layers 410, 420, 430, and 440. The first drain electrode D1 may be connected to another portion of the first active layer ACT1 through another contact hole of the first to fourth insulation layers 410, 420, 430, and 440.

The second source electrode S2 may be connected to a portion of the second active layer ACT2 through the contact hole between the fourth insulation layer 440 and the second sub insulation layer 520. The second drain electrode D2 may be connected to another portion of the second active layer ACT2 through another contact hole of the fourth insulation layer 440 and the second sub insulation layer 520.

The connection pattern CP may be disposed on the fourth insulation layer 440. The connection pattern CP may be integrally formed with the second source electrode S2 or the second drain electrode D2 or may be electrically connected to the second source electrode S2 or the second drain electrode D2. For example, the connection pattern CP may be formed of a first source-drain metal.

The connection pattern CP may be electrically connected to the lower pattern BSM through the contact holes of the first to fourth insulation layers 410, 420, 430, and 440 and the buffer layer 400.

The third capacitor electrode CAPE3 may be disposed on the fourth insulation layer 440. For example, the third capacitor electrode CAPE3 may be formed of a first source-drain metal.

The first capacitor electrode CAPE1, the second capacitor electrode CAPE2, and the third capacitor electrode CAPE3 may vertically overlap each other.

The first capacitor electrode CAPE1 may be formed of the same lower pattern metal as the lower pattern BSM, the second capacitor electrode CAPE2 may be formed of a gate metal, and the third capacitor electrode CAPE3 may be formed of a first source-drain metal.

The first capacitor electrode CAPE1 and the second capacitor electrode CAPE2 may form a first capacitor Cst1, and the second capacitor electrode CAPE2 and the third capacitor electrode CAPE3 may form a second capacitor Cst2.

The first capacitor electrode CAPE1 and the third capacitor electrode CAPE3 may be electrically connected to each other. The first capacitor electrode CAPE1 and the third capacitor electrode CAPE3 may be electrically separated from the third capacitor electrode CAPE3. For example, the first capacitor electrode CAPE1 and the third capacitor electrode CAPE3 may be electrically connected to the source electrode (or the drain electrode) of a transistor (e.g., the second transistor TFT2) in the subpixel SP. The third capacitor electrode CAPE3 may be electrically connected to the gate electrode of a transistor (e.g., the second transistor TFT2, etc.) in the subpixel SP.

Accordingly, the first capacitor Cst1 and the second capacitor Cst2 may be electrically connected in parallel. Accordingly, the storage capacitor Cst in the subpixel SP may include the first capacitor Cst1 and the second capacitor Cst2 connected in parallel. Accordingly, the capacitance of the storage capacitor Cst in the subpixel SP increases, and thus the driving performance of the subpixel SP may be enhanced.

A fifth insulation layer 700 may be disposed on the first source electrode S1, the first drain electrode D1, the second source electrode S2, and the second drain electrode D2.

The fifth insulation layer 700 may be formed of a fifth insulating material. The fifth insulating material may be different from the fourth insulating material of the fourth insulation layer 440 or the same as the fourth insulating material of the fourth insulation layer 440. For example, the fifth insulating material may include silicon oxide (SiOx).

The fifth insulation layer 700 is disposed between the first source-drain metal and the second source-drain metal and may also be referred to as a second interlayer insulation layer.

The first planarization layer 710 may be disposed on the fifth insulation layer 700. For example, the first planarization layer 710 may be an organic layer including an organic material.

The relay electrode RE may be disposed on the first planarization layer 710. The relay electrode RE may be formed of a second source-drain metal.

The relay electrode RE may be electrically connected to the second source electrode S2 or the second drain electrode D2 through the hole of the first planarization layer 710 and the fifth insulation layer 700.

The second planarization layer 720 may be disposed on the relay electrode RE. For example, the second planarization layer 720 may be an organic layer including an organic material.

Referring to FIG. 7, a bank 730 for defining a light emitting element ED and an emission area EA of the light emitting element ED may be disposed on the second planarization layer 720.

The light emitting element ED may be electrically connected to a second transistor TFT2. The light emitting element ED may include a pixel electrode PE, an intermediate layer EL, and a common electrode CE.

The pixel electrode PE may be disposed on the second planarization layer 720. The pixel electrode PE may be connected to the relay electrode RE through the hole of the second planarization layer 720.

A bank 730 may be disposed on the pixel electrode PE. A spacer 735 may be further disposed on the bank 730. For example, the bank 730 may be formed of an organic material. The spacer 735 may include an organic material and may be formed of the same material as the bank 730.

The bank 730 may have an opening for forming the light emitting element ED. The opening of the bank 730 may overlap at least a portion of the pixel electrode PE.

An intermediate layer EL may be disposed on the bank 730. The intermediate layer EL may contact at least a portion of the pixel electrode PE in the opening of the bank 730.

The common electrode CE may be disposed on the intermediate layer EL.

In the opening of the bank 730, the pixel electrode PE, the intermediate layer EL, and the common electrode CE may be stacked to form the light emitting element ED.

The bank 730 may include at least one trench TRC. At least one trench TRC may be present in at least one of the first area A1 and the second area A2.

Leakage current flowing to the side surface of the intermediate layer EL and/or the common electrode CE may be prevented or reduced by at least one trench TRC formed in the bank 730. In particular, when the light emitting element ED has a tandem structure, the effect of preventing or reducing leakage current by at least one trench TRC formed in the bank 730 may be further increased.

For example, in the area where the trench TRC of the bank 730 is formed, the intermediate layer EL and the common electrode CE may be continuously disposed along the inner surface of the trench TRC on the upper surface of the bank 730. As described above, even when the intermediate layer EL and the common electrode CE are not broken in the area where the trench TRC of the bank 730 is formed, the length of the intermediate layer EL and the common electrode CE in the lateral direction may be increased according to the shape of the trench TRC of the bank 730, so that leakage current flowing in the lateral direction of at least one of the intermediate layer EL and the common electrode CE may be decreased or prevented.

As another example, in the area where the trench TRC of the bank 730 is formed, the intermediate layer EL may be broken, but the common electrode CE may be continuously disposed along the inner surface of the trench TRC on the upper surface of the bank 730. As described above, as the intermediate layer EL is broken in the area where the trench TRC of the bank 730 is formed, leakage current flowing in the lateral direction of the intermediate layer EL may be decreased or prevented.

Referring to FIG. 7, the encapsulation layer 200 may be disposed on the common electrode CE.

The encapsulation layer 200 may prevent or reduce moisture or oxygen from penetrating into the light emitting element ED. For example, the encapsulation layer 200 may prevent or reduce moisture or oxygen from penetrating into the organic material included in the intermediate layer EL of the light emitting element ED. The encapsulation layer 200 may be formed of a single layer or multiple layers, but embodiments of the disclosure are not limited thereto.

For example, the encapsulation layer 200 may include a first encapsulation layer 740, a second encapsulation layer 750, and a third encapsulation layer 760, but embodiments of the disclosure are not limited thereto. For example, the first encapsulation layer 740 and the third encapsulation layer 760 may include an inorganic layer, and the second encapsulation layer 750 may include an organic layer, but embodiments of the disclosure are not limited thereto.

The display panel 110 according to embodiments of the disclosure may include a touch sensor. In this case, the display panel 110 according to embodiments of the disclosure may include a touch sensor layer 210 formed on the encapsulation layer 200. The touch sensor layer 210 may be a touch unit.

The touch sensor layer 210 may include a plurality of touch electrodes TE corresponding to touch sensors and may include a plurality of touch metal layers for forming the plurality of touch electrodes TE.

For example, the plurality of touch metal layers may include a first touch metal layer on which a plurality of first touch metals TM1 are disposed, and a second touch metal layer on which a plurality of second touch metals TM2 are disposed. In this case, the touch sensor layer 210 may include a touch inter-layer insulation layer 780 between the first touch metal layer and the second touch metal layer.

One of the first touch metal layer and the second touch metal layer may be a sensor metal layer and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming touch sensors, and the plurality of first touch metals TM1 disposed in the first touch metal layer may be bridge metals electrically connecting the plurality of second touch metals TM2, which are sensor metals.

As another example, the first touch metal layer may be a sensor metal layer, and the second touch metal layer may be a bridge metal layer. In this case, the plurality of first touch metals TM1 disposed in the first touch metal layer may be sensor metals forming touch sensors, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

The touch sensor layer 210 may include at least one insulation layer (or touch insulation layer).

For example, the touch sensor layer 210 may include a touch interlayer insulation layer 780 disposed between the first touch metal layer on which the plurality of first touch metals TM1 are disposed and the second touch metal layer on which the plurality of second touch metals TM2 are disposed. For example, the touch interlayer insulation layer 780 may be an inorganic layer including an inorganic insulating material or an organic layer including an organic insulating material.

As another example, the touch sensor layer 210 may further include a touch buffer layer 770 between the encapsulation layer 200 and the touch metal layer. The touch buffer layer 770 may be disposed between the encapsulation layer 200 and the first touch metal layer on which a plurality of first touch metals TM1 are disposed. Here, the touch buffer layer 770 may be omitted. For example, the touch buffer layer 770 may be an inorganic layer including an inorganic insulating material or an organic layer including an organic insulating material.

As another example, the touch sensor layer 210 may further include a touch protective layer 790 on the touch metal layer. The touch protective layer 790 may be disposed on the first touch metal layer on which a plurality of second touch metals TM2 are disposed. For example, the touch protective layer 790 may be an inorganic layer including an inorganic insulating material or an organic layer including an organic insulating material. The touch protective layer 790 may extend to an upper portion of the touch line TL. The touch protective layer 790 may further extend to an upper portion of the touch pad TP.

Each of the plurality of touch electrodes TE may be formed of at least one second touch metal TM2. Each of the plurality of touch electrodes TE may be a mesh type electrode having a plurality of openings, but embodiments of the disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through the first touch metals TM1, which are bridge metals. For example, the second touch metals TM2 spaced apart from each other may be electrically connected by the first touch metal TM1 to constitute one first touch electrode TE1.

The plurality of first touch metals TM1 may be disposed on the touch buffer layer 770. The touch interlayer insulation layer 780 may be disposed on the plurality of first touch metals TM1. The plurality of second touch metals TM2 may be disposed on the touch interlayer insulation layer 780. Some of the plurality of second touch metals TM2 may be connected to the corresponding first touch metal TM1 through a hole in the touch interlayer insulation layer 780.

The plurality of first touch metals TM1 and the plurality of second touch metals TM2 may be disposed not to overlap the light emitting element ED. The plurality of first touch metals TM1 and the plurality of second touch metals TM2 may overlap the bank 730.

The touch protective layer 790 may be disposed on the touch metal layer. The touch protective layer 790 may be disposed while covering the plurality of touch metals TM1 and TM2 disposed in the touch metal layer.

The touch electrodes TE1 and TE2 disposed on the touch sensor layer 210 may be disposed in the second area A2 where the second transistor TFT2 is disposed, out of the first area A1 and the second area A2. The touch electrodes TE1 and TE2 may overlap the bank 730 without overlapping the emission area EA of the light emitting element ED.

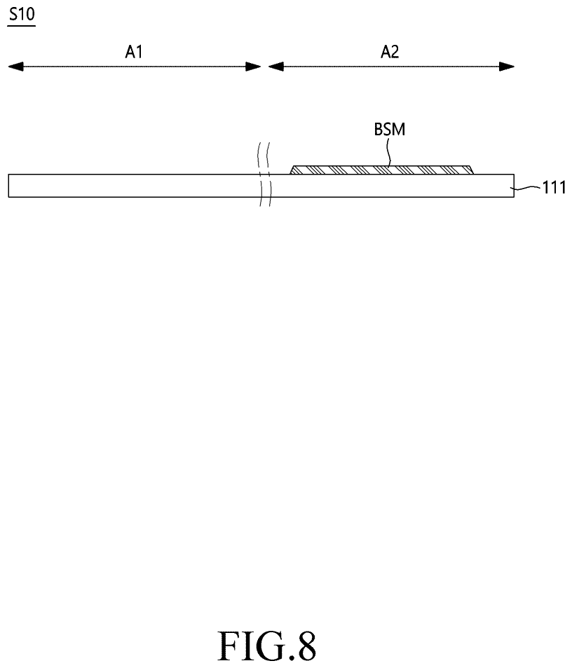

FIGS. 8 to 19 illustrate a manufacturing process flow of a display panel 110 according to embodiments of the disclosure.

Referring to FIG. 8, in the first step S10, the lower pattern BSM may be formed on the substrate 111.

The lower pattern BSM may be positioned in the second area A2.

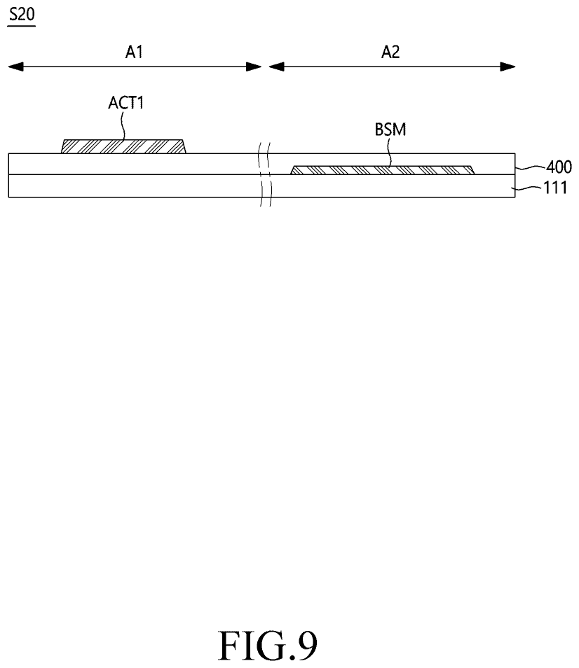

Referring to FIG. 9, in the second step S20, the buffer layer 400 may be formed on the lower pattern BSM. The first active layer ACT1 may be formed on the buffer layer 400.

The first active layer ACT1 may be positioned in the first area A1.

For example, the first active layer ACT1 may be a low-temperature polysilicon semiconductor material.

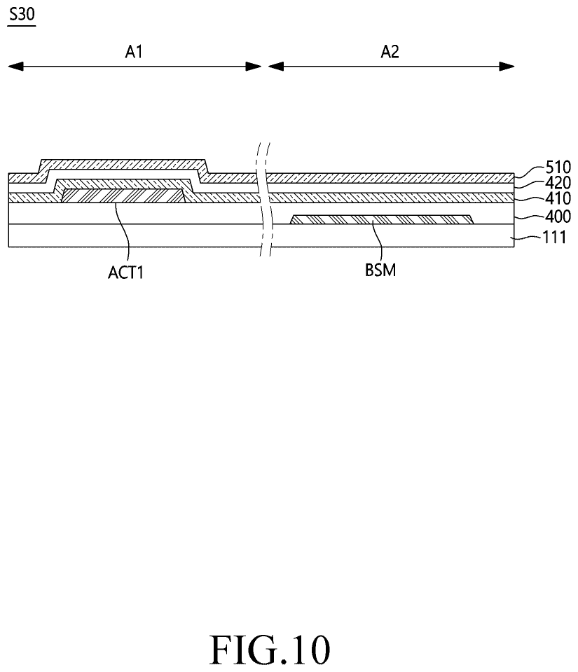

Referring to FIG. 10, in the third step S30, a deposition process may be performed on the first insulation layer 410, the second insulation layer 420, and the first sub insulation layer 510.

Through the deposition process of the third step S30, the first insulation layer 410 may be formed to cover the first active layer ACT1, the second insulation layer 420 may be formed on the first insulation layer 410, and the first sub insulation layer 510 may be formed on the second insulation layer 420.

For example, the first insulation layer 410 may include silicon oxide (SiOx), the second insulation layer 420 may include silicon nitride (SiNx), and the first sub insulation layer 510 may include silicon oxide (SiOx).

For example, the second insulation layer 420 formed through the deposition process in the third step S30 may include a large amount of hydrogen (H).

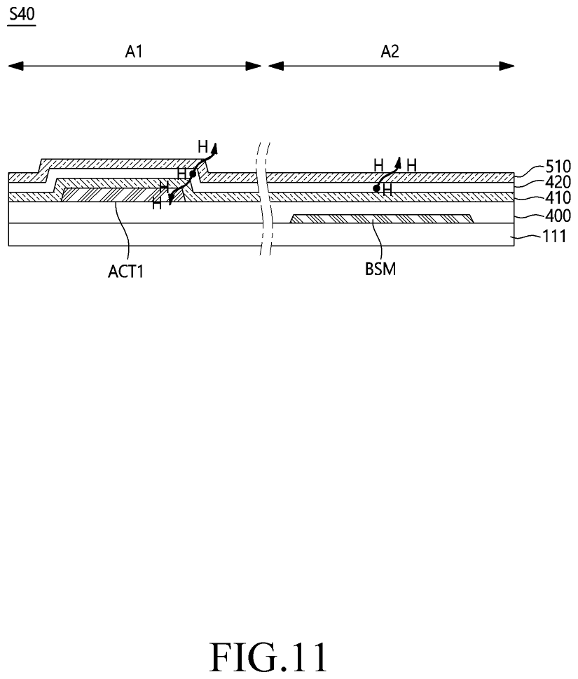

Referring to FIG. 11, in the fourth step S40, a first heat treatment process may be carried out.

Through the first heat treatment process, a large amount of hydrogen (H) included in the second insulation layer 420 may escape from the second insulation layer 420.

For example, the first transistor TFT1 may be a low-temperature polysilicon transistor, and the second transistor TFT2 may be an oxide transistor. In consideration of this example, the first heat treatment process of the fourth step S40 may be a hydrogenation process for the first active layer ACT1 and a dehydrogenation process around the second active layer ACT2.

Through the first heat treatment process, a large amount of hydrogen (H) released from the second insulation layer 420 may be supplied to the first active layer ACT1 including a low-temperature polysilicon semiconductor material to stabilize the first active layer ACT1. In this sense, the first heat treatment process may be a hydrogenation process for the first active layer ACT1.

Accordingly, the first active layer ACT1 may include hydrogen (H). According to the first heat treatment process, the first active layer ACT1 may include more hydrogen than the second active layer ACT2.

Since a large amount of hydrogen (H) included in the second insulation layer 420 has a bad effect on the second active layer ACT2 including the oxide semiconductor material, it is necessary to extract a large amount of hydrogen (H) from the second insulation layer 420. In other words, it may be necessary to dehydrate the second insulation layer 420. Therefore, the first heat treatment process of the fourth step S40 may be a dehydrogenation process of the second insulation layer 420 positioned around the second active layer ACT2 including the oxide semiconductor material. By the first heat treatment process of the fourth step S40, hydrogen is formed in the second area A2 and the influence on the second transistor TFT2, which is an oxide transistor, may be decreased.

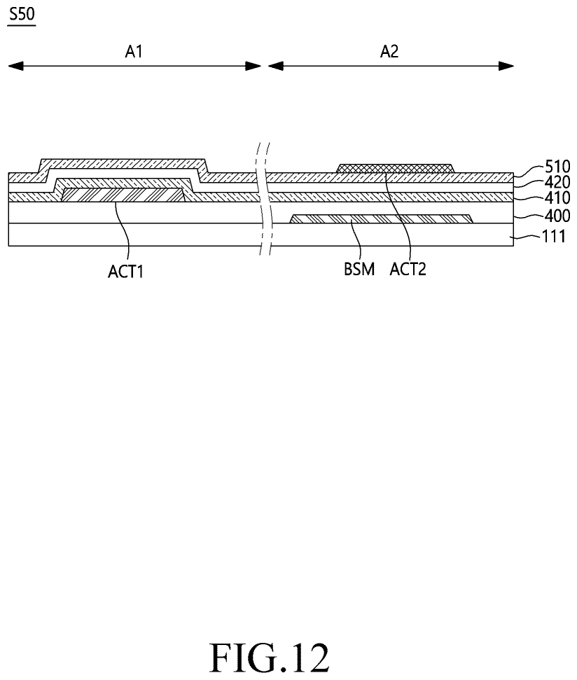

Referring to FIG. 12, in the fifth step S50, the second active layer ACT2 may be formed on the first sub insulation layer 510.

The second active layer ACT2 may be disposed in the second area A2.

For example, the second active layer ACT2 may include an oxide semiconductor material.

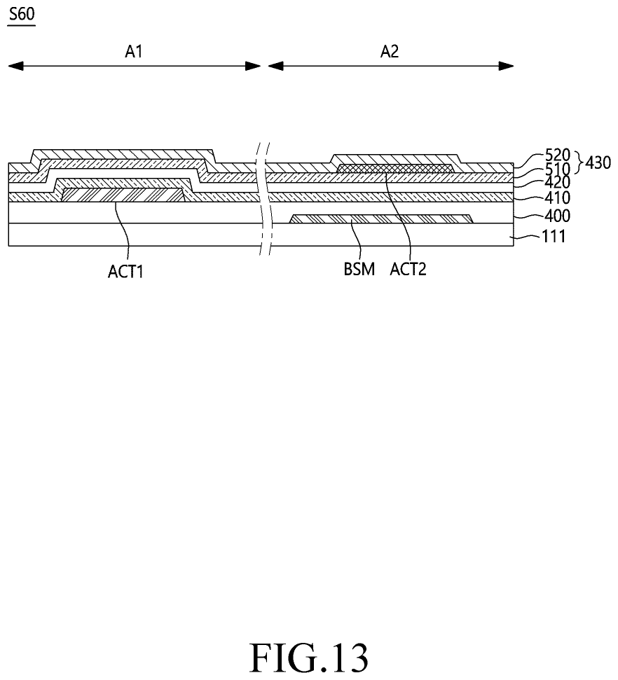

Referring to FIG. 13, in the sixth step S60, the second sub insulation layer 520 may be formed to cover the second active layer ACT2.

For example, the second sub insulation layer 520 may include the same insulating material as the first sub insulation layer 510. For example, the first sub insulation layer 510 and the second sub insulation layer 520 may include silicon oxide (SiOx).

The first sub insulation layer 510 and the second sub insulation layer 520 may constitute a third insulation layer 430. When the first sub insulation layer 510 and the second sub insulation layer 520 are formed of the same insulating material, the second active layer ACT2 may be considered to be buried in the third insulation layer 430.

Since the first sub insulation layer 510 and the second sub insulation layer 520 are formed of silicon oxide (SiOx), which is the same insulating material, hydrogen may be formed in the second area A2 and the effect on the second transistor TFT2 which is an oxide transistor may be effectively controlled.

The first insulation layer 410, the second insulation layer 420, and the third insulation layer 430 disposed between the first active layer ACT1 and the first gate electrode G1 may constitute the first gate insulation layer GI1 of the first transistor TFT1. The third insulation layer 430 may include a first sub insulation layer 510 and a second sub insulation layer 520.

The second sub insulation layer 520 disposed between the second active layer ACT2 and the second gate electrode G2 may constitute the second gate insulation layer GI2 of the second transistor TFT2.

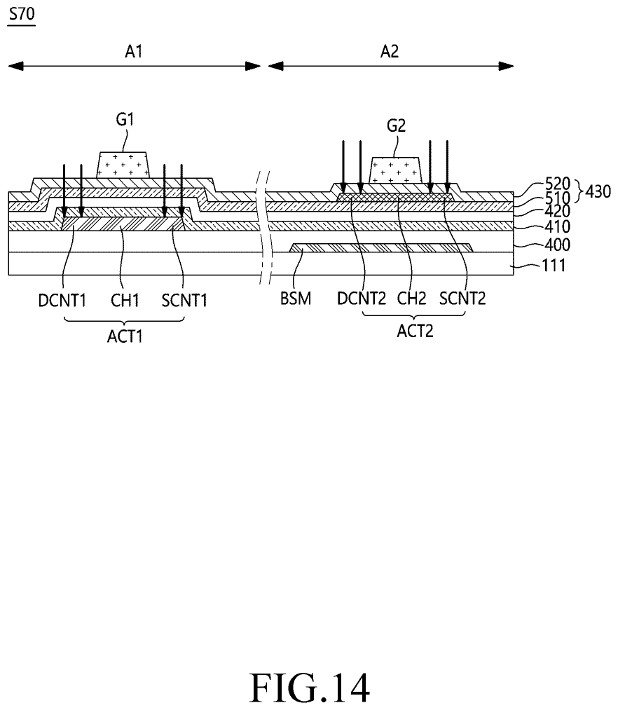

Referring to FIG. 14, in the seventh step S70, a gate forming process and a conductivity-forming process may be performed.

In the seventh step S70, the first gate electrode G1 and the second gate electrode G2 may be formed on the second sub insulation layer 520 through the gate formation process.

The first gate electrode G1 and the second gate electrode G2 may be formed of the same gate metal. The first gate electrode G1 and the second gate electrode G2 may be formed together. Accordingly, the number of masks and the number of processes may be decreased.

In the seventh step S70, the first source contact portion SCNT1 and the first drain contact portion DCNT1 of the first active layer ACT1 may be rendered conductive, and the second source contact portion SCNT2 and the second drain contact portion DCNT2 of the second active layer ACT2 may be rendered conductive through the conductivity-forming process. For example, the conductivity-forming process may be an ion doping process.

After the conductivity-forming process, the first active layer ACT1 may include a first channel portion CH1, a first source contact portion SCNT1 on one side of the first channel portion CH1, and a first drain contact portion DCNT1 on the other side of the first channel portion CH1. For example, the first source contact portion SCNT1 and the first drain contact portion DCNT1 may have higher electrical conductivity than the first channel portion CH1. The first channel portion CH1 may overlap the first gate electrode G1.

After the conductivity-forming process, the second active layer ACT2 may include a second channel portion CH2, a second source contact portion SCNT2 on one side of the second channel portion CH2, and a second drain contact portion DCNT2 on the other side of the second channel portion CH2. For example, the second source contact portion SCNT2 and the second drain contact portion DCNT2 may have higher electrical conductivity than the second channel portion CH2. The second channel portion CH2 may overlap the second gate electrode G2.

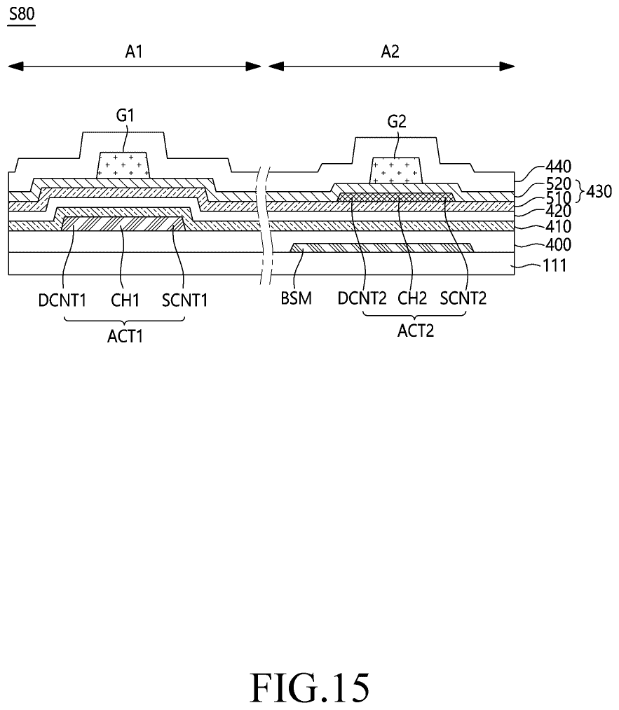

Referring to FIG. 15, in the eighth step S80, the fourth insulation layer 440 may be formed to cover the first gate electrode G1 and the second gate electrode G2.

For example, the fourth insulation layer 440 may be silicon oxide (SiOx).

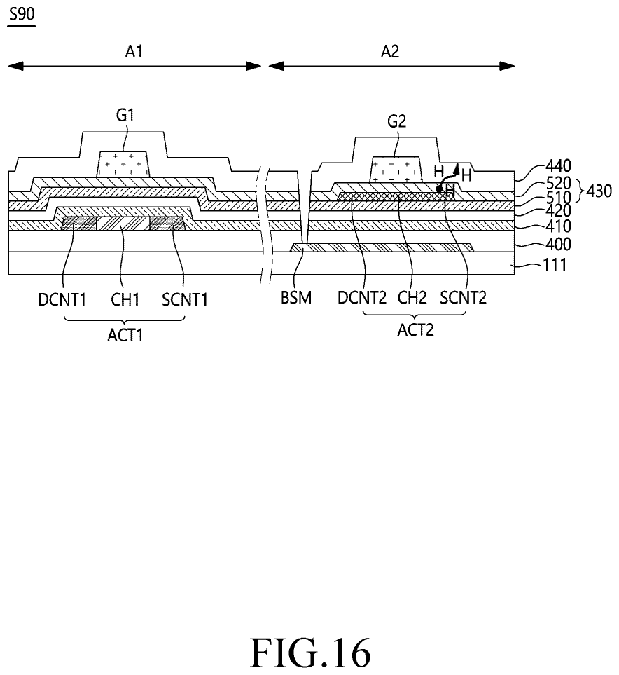

Referring to FIG. 16, a second heat treatment process may be carried out in the ninth step S90. The second heat treatment process may be referred to as an activation process of the first active layer ACT1 and a heat treatment process (dehydrogenation process) of the second gate insulation layer GI2.

Through the second heat treatment process of the ninth step S90, contact resistance of each of the first source contact portion SCNT1 and the first drain contact portion DCNT1 of the first active layer ACT1 may be decreased. In this sense, the second heat treatment process may be referred to as an activation process of the first active layer ACT1.

According to the conductivity-forming process (e.g., an ion doping process) of the seventh step S70, the crystals of the first source contact portion SCNT1 and the first drain contact portion DCNT1 of the first active layer ACT1 are broken, and thus the contact resistance may be slightly increased. Therefore, through the second heat treatment process of the ninth step S90, the contact resistance of each of the first source contact portion SCNT1 and the first drain contact portion DCNT1 of the first active layer ACT1 may be decreased.

Further, hydrogen included in the second sub insulation layer 520, which is the second gate insulation layer GI2 between the second active layer ACT2 and the second gate electrode G2, may be extracted through the second heat treatment process of the ninth step S90. The second heat treatment process in the ninth step S90 may be a dehydration process for the second sub insulation layer 520, which is the second gate insulation layer GI2 of the second transistor TFT2. In this sense, the second heat treatment process may be referred to as a heat treatment process (dehydrogenation process) of the second gate insulation layer GI2.

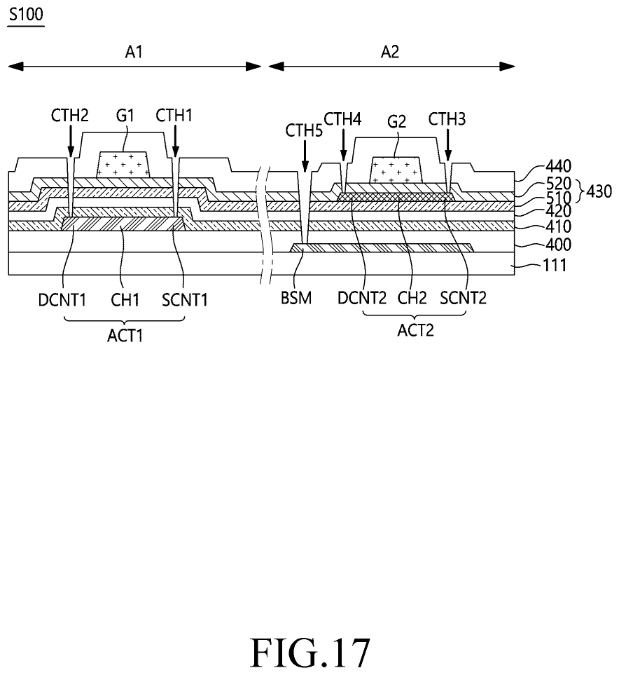

Referring to FIG. 17, in the tenth step S100, a plurality of contact holes CTH1, CTH2, CTH3, CTH4, and CTH5 may be formed.

In the first area A1, each of the first contact hole CTH1 and the second contact hole CTH2 may be a hole penetrating the first to fourth insulation layers 410, 420, 430, and 440. The third insulation layer 430 may include a first sub insulation layer 510 and a second sub insulation layer 520.

The first contact hole CTH1 may overlap at least a portion of the first source contact portion SCNT1 of the first active layer ACT1, and the second contact hole CTH2 may overlap at least a portion of the first drain contact portion DCNT1 of the first active layer ACT1.

In the second area A2, each of the third contact hole CTH3 and the fourth contact hole CTH4 may be a hole penetrating the fourth insulation layer 440 and the second sub insulation layer 520.

The third contact hole CTH3 may overlap at least a portion of the second source contact portion SCNT2 of the second active layer ACT2, and the fourth contact hole CTH4 may overlap at least a portion of the second drain contact portion DCNT2 of the second active layer ACT2.

In the second area A2, the fifth contact hole CTH5 may be a hole penetrating the first to fourth insulation layers 410, 420, 430, and 440 and the buffer layer 400.

The fifth contact hole CTH5 may overlap at least a portion of the lower pattern BSM.

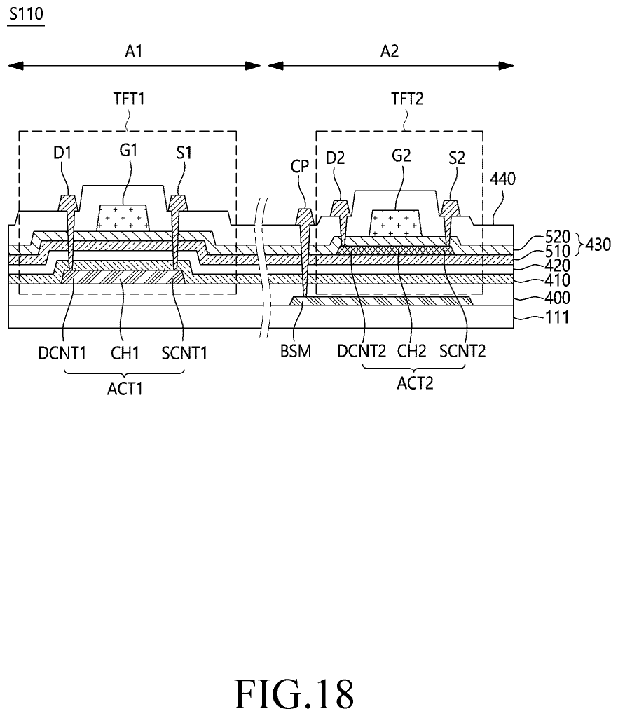

Referring to FIG. 18, in the eleventh step S110, a source-drain forming process may be performed.

In the eleventh step S110, the first source electrode S1 and the first drain electrode D1 of the first transistor TFT1 and the second source electrode S2 and the second drain electrode D2 of the second transistor TFT2 may be formed on the fourth insulation layer 440 through the source-drain forming process. For example, the first source electrode S1 and the first drain electrode D1 of the first transistor TFT1 and the second source electrode S2 and the second drain electrode D2 of the second transistor TFT2 may be formed of the same first source-drain metal.

The first source electrode S1 and the first drain electrode D1 of the first transistor TFT1 may be positioned in the first area A1, and the second source electrode S2 and the second drain electrode D2 of the second transistor TFT2 may be positioned in the second area A2.

The first source electrode S1 of the first transistor TFT1 may be electrically connected to the first source contact portion SCNT1 of the first active layer ACT1 through the first contact hole CTH1, and the first drain electrode D1 of the first transistor TFT1 may be electrically connected to the first drain contact portion DCNT1 of the first active layer ACT1 through the second contact hole CTH2.

The second source electrode S2 of the second transistor TFT2 may be electrically connected to the second source contact portion SCNT2 of the second active layer ACT2 through the third contact hole CTH3, and the second drain electrode D2 of the second transistor TFT2 may be electrically connected to the second drain contact portion DCNT2 of the second active layer ACT2 through the fourth contact hole CTH4.

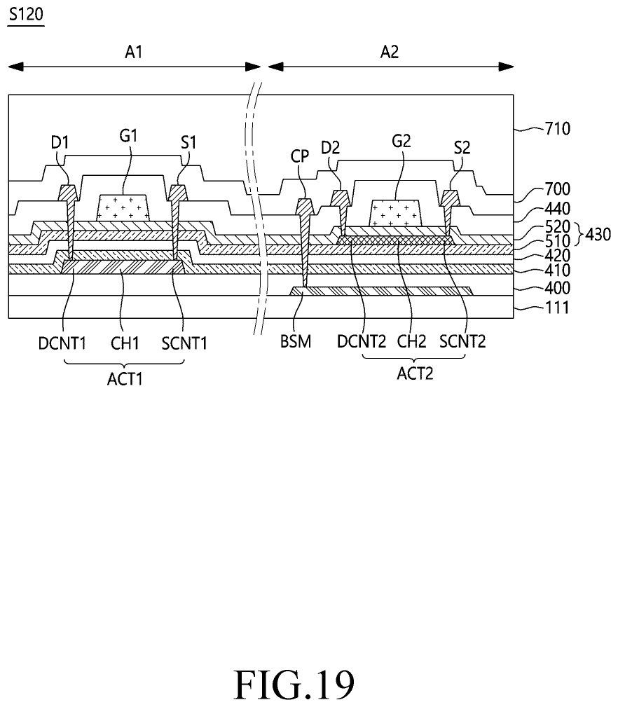

Referring to FIG. 19, in the twelfth step S120, the fifth insulation layer 700 and the first planarization layer 710 may be formed.

In the twelfth step S120, the fifth insulation layer 700 may be formed to cover the first source electrode S1 and the first drain electrode D1 of the first transistor TFT1, and the second source electrode S2 and the second drain electrode D2 of the second transistor TFT2.

In the twelfth step S120, the first planarization layer 710 may be disposed on the fifth insulation layer 700.

Embodiments of the disclosure described above are briefly described below.

A display device according to embodiments of the disclosure may comprise a substrate, a first active layer disposed on the substrate and positioned in a first area, a first insulation layer disposed on the first active layer, a second insulation layer disposed on the first insulation layer, a third insulation layer disposed on the second insulation layer, a second active layer disposed on the substrate and positioned in a second area different from the first area, a first gate electrode disposed on the third insulation layer and overlapping at least a portion of the first active layer, a second gate electrode disposed on the third insulation layer and overlapping at least a portion of the second active layer, and a fourth insulation layer disposed on the first gate electrode and the second gate electrode.

According to the display device according to embodiments of the disclosure, the second insulation layer may be disposed on the first active layer and disposed under the second active layer.

According to the display device according to embodiments of the disclosure, the second active layer may be buried in the third insulation layer. The third insulation layer may be disposed to surround an upper surface, a lower surface, and a side surface of the second active layer. The third insulation layer may be positioned between the second insulation layer and the first gate electrode, between the second insulation layer and the second active layer, and between the second active layer and the second gate electrode. The third insulation layer may be positioned on a side of the second active layer.

According to the display device according to embodiments of the disclosure, the first gate electrode and the second gate electrode may include the same gate metal.

According to the display device according to embodiments of the disclosure, the third insulation layer may include a first sub insulation layer disposed between the second insulation layer and the second active layer, and a second sub insulation layer disposed between the second active layer and the second gate electrode.

According to the display device according to embodiments of the disclosure, out of the first sub insulation layer and the second sub insulation layer, the second sub insulation layer may be disposed between the second active layer and the second gate electrode, and the first sub insulation layer may be disposed under the second active layer.

According to the display device according to embodiments of the disclosure, the first sub insulation layer and the second sub insulation layer may be disposed between the first active layer and the first gate electrode.

The display device according to embodiments of the disclosure may further comprise a first source electrode disposed on the fourth insulation layer and electrically connected to a first source contact portion of the first active layer through a first contact hole, a first drain electrode disposed on the fourth insulation layer and electrically connected to a first drain contact portion of the first active layer through a second contact hole, a second source electrode disposed on the fourth insulation layer and electrically connected to a second source contact portion of the second active layer through a third contact hole, and a second drain electrode disposed on the fourth insulation layer and electrically connected to a second drain contact portion of the second active layer through a fourth contact hole.

According to the display device according to embodiments of the disclosure, each of the first contact hole and the second contact hole may penetrate the first to fourth insulation layers, and each of the third contact hole and the fourth contact hole may penetrates the second sub insulation layer and the fourth insulation layer.

According to the display device according to embodiments of the disclosure, the first insulation layer, the second insulation layer, and the third insulation layer may constitute a first gate insulation layer between the first active layer and the first gate electrode. The second sub insulation layer may constitute a second gate insulation layer between the second active layer and the second gate electrode.

The display device according to embodiments of the disclosure may further comprise a buffer layer disposed between the substrate and the first insulation layer, and a lower pattern disposed between the buffer layer and the first insulation layer and overlapping at least a portion of one of the first active layer and the second active layer.

According to the display device according to embodiments of the disclosure, the lower pattern may be positioned in the second area.

The display device according to embodiments of the disclosure may further comprise a connection pattern disposed on the fourth insulation layer. The connection pattern may be electrically connected to the lower pattern through a fifth contact hole penetrating the first to fourth insulation layers and the buffer layer.

According to the display device according to embodiments of the disclosure, the first active layer may include a polysilicon semiconductor material, and the second active layer may include an oxide semiconductor material.

According to the display device according to embodiments of the disclosure, the first insulation layer may include a first insulating material, the second insulation layer may include a second insulating material, and the third insulation layer may include a third insulating material. The second insulating material may be different from the first insulating material and the third insulating material.

According to the display device according to embodiments of the disclosure, the second insulating material may include nitrogen. The first insulating material and the third insulating material may not include nitrogen but include oxygen.

According to the display device according to embodiments of the disclosure, the fourth insulation layer may include a fourth insulating material different from the second insulating material.

According to the display device according to embodiments of the disclosure, the third insulation layer may include a first sub insulation layer disposed between the second insulation layer and the second active layer, and a second sub insulation layer disposed between the second active layer and the second gate electrode. The insulating material included in the first sub insulation layer and the insulating material included in the second sub insulation layer may be the same as each other. The insulating material included in the first sub insulation layer and the insulating material included in the second sub insulation layer may be different from an insulating material included in the second insulation layer.

According to the display device according to embodiments of the disclosure, the first area may be included in a non-display area where an image is not displayed, and the second area may be included in a display area where an image is displayed.

According to the display device according to embodiments of the disclosure, the first area may be included in an area where a gate-in-panel circuit is disposed, and the second area may be included in an area where a subpixel is disposed.

A display device according to embodiments of the disclosure may comprise a substrate, a first transistor disposed on the substrate and positioned in a first area, and a second transistor disposed on the substrate and positioned in a second area different from the first area. The first transistor may include a first active layer disposed on the substrate and positioned in the first area, a first gate insulation layer disposed on the first active layer, and a first gate electrode disposed on the first gate insulation layer and overlapping at least a portion of the first active layer. The second transistor may include a second active layer disposed on the substrate and positioned in the second area, a second gate insulation layer disposed on the second active layer, and a second gate electrode disposed on the second gate insulation layer and overlapping at least a portion of the second active layer.

According to the display device according to embodiments of the disclosure, the first gate insulation layer may include an insulating material not included in the second gate insulation layer. According to the display device according to embodiments of the disclosure, the first gate insulation layer may include a first insulation layer including a first insulating material, a second insulation layer including a second insulating material, and a third insulation layer including the first insulating material.

The first insulation layer and the second insulation layer may be disposed on the first active layer and disposed under the second active layer. The second gate insulation layer may include the first insulating material but may not include the second insulating material.

The display device according to embodiments of the disclosure may further comprise a gate line to which a gate signal output from the first transistor is applied, and a light emitting element electrically connected to the second transistor.

The display device according to embodiments of the disclosure may further comprise a bank for defining an emission area of the light emitting element. The bank may include at least one trench.

According to the display device according to embodiments of the disclosure, the first active layer may be positioned closer to the substrate than the second active layer. The first active layer and the second active layer may include different semiconductor materials.

A display device according to embodiments of the disclosure may comprise a substrate, a first transistor disposed on the substrate and positioned in a first area, a second transistor disposed on the substrate and positioned in a second area different from the first area, an insulation layer disposed on the first transistor and the second transistor, and a touch electrode disposed on the insulation layer.

The first transistor may include a first active layer disposed on the substrate and positioned in the first area, a first gate insulation layer disposed on the first active layer, and a first gate electrode disposed on the first gate insulation layer and overlapping at least a portion of the first active layer.

The second transistor may include a second active layer disposed on the substrate and positioned in the second area, a second gate insulation layer disposed on the second active layer, and a second gate electrode disposed on the second gate insulation layer and overlapping at least a portion of the second active layer.

According to the display device according to embodiments of the disclosure, the first gate electrode and the second gate electrode may include the same gate metal. The first active layer may be positioned closer to the substrate than the second active layer.

According to the display device according to embodiments of the disclosure, the touch electrode may be disposed in the second area where the second transistor may be disposed, out of the first area and the second area.

According to the display device according to embodiments of the disclosure, the first gate insulation layer may include an insulating material not included in the second gate insulation layer.

According to the display device according to embodiments of the disclosure, the first gate insulation layer may include a first insulation layer disposed on the first active layer, a second insulation layer disposed on the first insulation layer, and a third insulation layer disposed on the second insulation layer.

According to the display device according to embodiments of the disclosure, the first gate electrode may be disposed on the third insulation layer. The second insulation layer positioned between the first insulation layer and the third insulation layer may include an insulating material different from the first insulation layer and the third insulation layer.

According to the display device according to embodiments of the disclosure, the third insulation layer may include a first sub insulation layer disposed between the second insulation layer and the second active layer, and a second sub insulation layer disposed between the second active layer and the second gate electrode.

According to the display device according to embodiments of the disclosure, out of the first sub insulation layer and the second sub insulation layer, the second sub insulation layer may be disposed between the second active layer and the second gate electrode, and the first sub insulation layer may be disposed under the second active layer. The first sub insulation layer and the second sub insulation layer may be disposed between the first active layer and the first gate electrode.

A display device according to embodiments of the disclosure may further comprise a light emitting element electrically connected to the second transistor, and a bank for defining an emission area of the light emitting element. The touch electrode may vertically overlap the bank without vertically overlapping the emission area of the light emitting element.

According to the display device according to embodiments of the disclosure, the first active layer may include more hydrogen than the second active layer.

According to embodiments of the disclosure described above, there may be provided a display device having a transistor structure having a structure capable of reducing the number of masks and the number of processes.

According to embodiments of the disclosure, there may be provided a display device having a different transistor structure for each area.

According to embodiments of the disclosure, there may be provided a display device having a transistor structure having a different active layer for each area.

According to embodiments of the disclosure, there may be provided a display device having a structure capable of reducing the thickness of a display panel and a structure capable of reducing the numbers of masks and processes, despite having a different transistor structure for each area.

According to embodiments of the disclosure, there may be provided a display device having a gate sharing structure while having a different transistor structure for each area. Thus, the thickness of the display panel may be reduced, and the numbers of masks and processes during the manufacturing of the display panel may be reduced.

According to embodiments of the disclosure, there may be provided a display device having a gate insulation sharing structure while having a different transistor structure for each area. Thus, the thickness of the display panel may be reduced, and the numbers of masks and processes during the manufacturing of the display panel may be reduced.

According to embodiments of the disclosure, there may be provided a display device capable of process optimization through a structure capable of reducing the number of masks and the number of processes.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the technical idea and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate;
a first active layer on the substrate, the first active layer positioned in a first area;
a first insulation layer on the first active layer;
a second insulation layer on the first insulation layer;
a third insulation layer on the second insulation layer;
a second active layer on the substrate, the second active layer positioned in a second area that is different from the first area;
a first gate electrode on the third insulation layer, the first gate electrode overlapping at least a portion of the first active layer;
a second gate electrode on the third insulation layer, the second gate electrode overlapping at least a portion of the second active layer; and
a fourth insulation layer on the first gate electrode and the second gate electrode,
wherein the second insulation layer is on the first active layer and disposed under the second active layer,
wherein the third insulation layer surrounds an upper surface, a lower surface, and a side surface of the second active layer, and
wherein the third insulation layer is between the second insulation layer and the first gate electrode, between the second insulation layer and the second active layer, and between the second active layer and the second gate electrode.

2. The display device of claim 1, wherein the first gate electrode and the second gate electrode include a same gate metal.

3. The display device of claim 1, wherein the third insulation layer includes:
a first sub insulation layer between the second insulation layer and the second active layer; and
a second sub insulation layer between the second active layer and the second gate electrode, and
wherein the first sub insulation layer and the second sub insulation layer are between the first active layer and the first gate electrode.

4. The display device of claim 3, further comprising:
a first source electrode on the fourth insulation layer, the first source electrode electrically connected to a first source contact portion of the first active layer through a first contact hole;
a first drain electrode on the fourth insulation layer, the first drain electrode electrically connected to a first drain contact portion of the first active layer through a second contact hole;
a second source electrode on the fourth insulation layer, the second source electrode electrically connected to a second source contact portion of the second active layer through a third contact hole; and
a second drain electrode on the fourth insulation layer, the second drain electrode electrically connected to a second drain contact portion of the second active layer through a fourth contact hole,
wherein each of the first contact hole and the second contact hole penetrates the first insulation layer, the second insulation layer, the third insulation layer, and the fourth insulation layer, and
wherein each of the third contact hole and the fourth contact hole penetrates the second sub insulation layer and the fourth insulation layer.

5. The display device of claim 3, further comprising:
a first gate insulation layer between the first active layer and the first gate electrode which comprises the first insulation layer, the second insulation layer, and the third insulation layer constitute, and
a second gate insulation layer between the second active layer and the second gate electrode which comprises the second sub insulation layer constitutes.

6. The display device of claim 3, wherein an insulating material included in the first sub insulation layer and an insulating material included in the second sub insulation layer are a same as each other, and
wherein the insulating material included in the first sub insulation layer and the insulating material included in the second sub insulation layer are different from an insulating material included in the second insulation layer.

7. The display device of claim 1, further comprising:
a buffer layer between the substrate and the first insulation layer; and
a lower pattern between the buffer layer and the first insulation layer, the lower pattern overlapping the second active layer and positioned in the second area.

8. The display device of claim 7, further comprising:
a connection pattern on the fourth insulation layer, the connection pattern electrically connected to the lower pattern through a fifth contact hole penetrating the first insulation layer, the second insulation layer, the third insulation layer, the fourth insulation layer, and the buffer layer.

9. The display device of claim 1, wherein the first active layer is closer to the substrate than the second active layer and the first active layer and the second active layer include different semiconductor materials.

10. The display device of claim 1, wherein the first insulation layer includes a first insulating material, the second insulation layer includes a second insulating material, and the third insulation layer includes a third insulating material, and
wherein the second insulating material is different from the first insulating material and the third insulating material.

11. The display device of claim 10, wherein the second insulating material includes nitrogen and the first insulating material and the third insulating material do not include nitrogen but include oxygen.

12. The display device of claim 1, wherein the first area is in a non-display area of the display device where an image is not displayed and the second area is in a display area of the display device where the image is displayed.

13. The display device of claim 1, wherein the first area is in an area of the display device where a gate-in-panel circuit is disposed and the second area is in an area of the display device where a subpixel is disposed.

14. A display device, comprising:
a substrate;
a first transistor on the substrate, the first transistor positioned in a first area; and
a second transistor on the substrate, the second transistor positioned in a second area that is different from the first area,
wherein the first transistor includes:
a first active layer on the substrate, the first active layer positioned in the first area;
a first gate insulation layer on the first active layer; and
a first gate electrode on the first gate insulation layer, the first gate electrode overlapping at least a portion of the first active layer,
wherein the second transistor includes:
a second active layer on the substrate, the second active layer positioned in the second area;
a second gate insulation layer on the second active layer; and
a second gate electrode on the second gate insulation layer, the second gate electrode overlapping at least a portion of the second active layer, and
wherein the first gate insulation layer includes an insulating material which is not included in the second gate insulation layer.

15. The display device of claim 14, wherein the first gate insulation layer includes a first insulation layer including a first insulating material, a second insulation layer including a second insulating material, and a third insulation layer including the first insulating material,
wherein the first insulation layer and the second insulation layer are on the first active layer and disposed under the second active layer, and
wherein the second gate insulation layer includes the first insulating material but does not include the second insulating material.

16. The display device of claim 14, further comprising:
a gate line to which a gate signal output from the first transistor is applied; and
a light emitting element electrically connected to the second transistor.

17. The display device of claim 16, further comprising:
a bank that defines an emission area of the light emitting element, the bank including at least one trench.

18. A display device, comprising:
a substrate;
a first transistor on the substrate, the first transistor positioned in a first area;
a second transistor on the substrate, the second transistor positioned in a second area that is different from the first area;
an insulation layer on the first transistor and the second transistor; and
a touch electrode on the insulation layer, the first transistor including:
a first active layer on the substrate, the first active layer positioned in the first area;
a first gate insulation layer on the first active layer; and
a first gate electrode on the first gate insulation layer, the first gate electrode overlapping at least a portion of the first active layer,
wherein the second transistor includes:
a second active layer on the substrate, the second active layer positioned in the second area;
a second gate insulation layer on the second active layer; and
a second gate electrode on the second gate insulation layer, the second gate electrode overlapping at least a portion of the second active layer,
wherein the first gate electrode and the second gate electrode include a same gate metal,
wherein the first active layer is closer to the substrate than the second active layer, and
wherein the touch electrode is in the second area where the second transistor is disposed, among the first area and the second area.

19. The display device of claim 18, wherein the first gate insulation layer includes an insulating material which is not included in the second gate insulation layer.

20. The display device of claim 18, wherein the first active layer includes more hydrogen than the second active layer.
